(19) United States
(12) Patent Application Publication
(10) Pub. No.: US 2025/0340974 A1
(43) Pub. Date: Nov. 6, 2025

(54) DEPOSITION APPARATUS AND METHOD OF MANUFACTURING THE SAME

(71) Applicant: Samsung Display Co., LTD., Yongin-si (KR)

(72) Inventor: DUCKJUNG LEE, Yongin-si (KR)

(21) Appl. No.: 19/009,147

(22) Filed: Jan. 3, 2025

(30) Foreign Application Priority Data
May 3, 2024 (KR) 10-2024-0059215

(51) Int. Cl. C23C 14/24; C23C 14/04

(52) U.S. Cl. CPC C23C 14/24; C23C 14/042

(57) ABSTRACT

A deposition apparatus includes: a voltage generator including a first contact portion configured to apply a first voltage and a second contact portion configured to apply a second voltage having an opposite polarity to the first voltage; a grid member having conductivity, electrically connected to the first contact portion, and defining first openings therein; and a mask disposed on the grid member, electrically connected to the second contact portion, and including a base substrate defining second openings therein, and an insulating film surrounding the base substrate and defining third openings therein on a top surface of the base substrate and fourth openings therein on a bottom surface of the base substrate.

This application claims priority to Korean Patent Application No. 10-2024-0059215, filed on May 3, 2024, and all the benefits accruing therefrom under 35 U.S.C. § 119, the content of which in its entirety is herein incorporated by reference.

### BACKGROUND

### 1. Field

A present disclosure relates to a deposition apparatus and method of manufacturing the same. More specifically, the present disclosure relates to a deposition apparatus that minimizes distortion during a deposition process and method of manufacturing the same.

### 2. Discussion of the Background

When forming an organic light emitting diode that constitutes an organic light emitting display device, an organic material layer, etc. is formed by depositing a deposition material evaporated from an evaporation source of an evaporation device on a substrate through a mask on which a pixel pattern is formed. In the deposition apparatus, the evaporation source is installed at a bottom of the chamber, the substrate is disposed at a top of the chamber, and deposition is performed on a lower surface of the substrate.

In this case, as a size of the substrate increases, a size of the mask also increases, causing a center of the mask to sag, which is a factor that reduces deposition precision. To solve this problem, research is being conducted to improve a sagging phenomenon by placing a grid member under the mask and attaching it by electrostatic force.

### SUMMARY

An aspect of the present disclosure is to provide a deposition apparatus with improved display reliability.

Another aspect of the present disclosure is to provide a method of manufacturing the deposition apparatus.

A deposition apparatus according to an embodiment of the present disclosure includes: a voltage generator including a first contact portion configured to apply a first voltage and a second contact portion configured to apply a second voltage having an opposite polarity to the first voltage; a grid member having conductivity, electrically connected to the first contact portion, and defining first openings therein; and a mask disposed on the grid member, electrically connected to the second contact portion, and including a base substrate defining second openings therein, and an insulating film surrounding the base substrate and defining third openings therein on a top surface of the base substrate and fourth openings therein on a bottom surface of the base substrate.

In an embodiment, the first openings may correspond one-to-one with the second openings.

In an embodiment, two or more third openings among the third openings may correspond to each of the second openings.

In an embodiment, the fourth openings may correspond one-to-one with the second openings.

In an embodiment, the first contact portion may contact a first contact area on a side of the grid member.

In an embodiment, the base substrate may have conductivity and be electrically connected to the second contact portion, the second contact portion may contact a second contact area on a side of the base substrate, and the insulating film may define a side opening therein exposing the second contact area on a side of the base substrate.

In an embodiment, each of the second contact portion, the second contact area, and the side opening may be provided in plural numbers.

In an embodiment, the insulating film may be a single layer or a multilayer.

In an embodiment, the mask and the grid member physically may contact with each other.

In an embodiment, the first contact portion and the second contact portion may be spaced apart from each other in a plan view.

In an embodiment, each of the second openings may have a trapezoidal shape in a cross-sectional view.

In an embodiment, the mask may further include a lower electrode layer disposed under the insulating film, having conductivity, and electrically connected to the second contact portion, and a lower insulating layer disposed under the lower electrode layer.

In an embodiment, the lower electrode layer may define fifth openings therein, which correspond one-to-one with the fourth openings, and the lower insulating layer defines sixth openings therein, which correspond one-to-one with the fifth openings.

In an embodiment, the second contact portion may contact a third contact area on a side of the lower electrode layer.

In an embodiment, the lower electrode layer may be electrically insulated from the base substrate.

In an embodiment, the lower insulating layer and the grid member may physically contact with each other.

In an embodiment, the lower insulating layer may include a same material as the insulating film.

A method of manufacturing the deposition apparatus according to an embodiment of the present disclosure includes: providing a base substrate having conductivity, forming an insulating film surrounding the base substrate, forming first openings in the insulating film on a top surface of the base substrate and second openings in the insulating film on a bottom surface of the base substrate, forming third openings in the base substrate corresponding one-to-one with the second openings, forming a side opening in the insulating film exposing a contact area on a side of the base substrate, and disposing a grid member under the insulating film, which has conductivity and defines fourth openings therein, which correspond one-to-one with the third openings

In an embodiment, the side opening may be provided in a plurality.

In an embodiment, two or more first openings among the first openings may correspond to each of the third openings.

A deposition apparatus according to an embodiment of the present disclosure may include a voltage generator including a first contact portion that applies a first voltage and a second contact portion that applies a second voltage having an opposite polarity to the first voltage, a grid member having conductivity, is electrically connected to the first contact portion, and defining first openings, and a mask disposed on the grid member, electrically connected to the second contact portion, and including a base substrate defining second openings, and an insulating film surrounding the base substrate and defining third openings on a top surface of the base substrate and fourth openings on a bottom surface of the base substrate.

Accordingly, the grid member may support the base substrate so that the base substrate does not sag in one direction (e.g., gravity direction). That is, as the grid member supports the base substrate, distortion, unevenness, etc. of the base substrate may be prevented or reduced. In addition, opposing voltages are applied to the grid member and the base substrate to generate a monopolar electrostatic force, so that the grid member and the base substrate may be effectively attracted to each other more strongly than a bipolar electrostatic force.

### BRIEF DESCRIPTION OF THE DRAWINGS

The accompanying drawings, which are included to provide a further understanding of the invention and are incorporated in and constitute a part of this specification, illustrate embodiments of the invention together with the description.

FIG. 1 is a cross-sectional view showing a deposition facility according to an embodiment of the present disclosure.

FIG. 2 is a cross-sectional view showing an embodiment of a deposition apparatus disposed inside the chamber of FIG. 1.

FIG. 3 is a cross-sectional view showing an enlarged embodiment of part A of FIG. 2.

FIG. 4 is a cross-sectional view showing another embodiment of enlarged part A of FIG. 2.

FIG. 5 is a perspective view showing the mask and grid member of FIG. 2.

FIG. 6 is a plan view showing an embodiment of the grid member of FIG. 5.

FIG. 7 is a plan view showing an embodiment of the mask of FIG. 5.

FIG. 8 is a cross-sectional view showing another embodiment of the deposition apparatus disposed inside the chamber of FIG. 1.

FIGS. 9, 10, 11, 12, 13, 14, and 15 are views showing a method of manufacturing the deposition apparatus of FIG. 2.

FIGS. 16, 17, 18, 19, 20 and 21 are views showing a method of manufacturing the deposition apparatus of FIG. 8.

### DETAILED DESCRIPTION

Regarding embodiments of the present disclosure disclosed in this text, specific structural and functional descriptions are merely illustrative for a purpose of explaining the embodiments of the present disclosure, and the embodiments of the present disclosure may be implemented in various forms and should not be construed as limited to the embodiments described in.

Since the present disclosure may be subject to various changes and may have various forms, specific embodiments will be illustrated in the drawings and described in detail in the text. However, this is not intended to limit the present disclosure to a specific disclosed form, and should be understood to include all changes, equivalents, and substitutes included in the spirit and technical scope of the present disclosure.

Terms such as “first”, “second”, etc. may be used to describe various components, but the components should not be limited by the terms. The above terms may be used for a purpose of distinguishing one component from another component. For example, a first component may be referred to as a second component, and similarly, the second component may be referred to as a first component without departing from the scope of the present disclosure.

It will be understood that when an element is referred to as being “connected” or “coupled” to another element, it may be directly connected or coupled to the other element or intervening element(s) may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for a purpose of describing particular example embodiments only and is not intended to be limiting of the present invention. As used herein, the singular forms “a,” “an” and “the” are intended to include plural forms as well, unless the context clearly indicates otherwise. It will be further understood that the terms “comprises” and/or “comprising,” when used in this specification, specify a presence of stated features, integers, steps, operations, elements, and/or components, but do not preclude the presence or addition of one or more other features, integers, steps, operations, elements, components, and/or groups thereof.

Terms such as “below”, “at the bottom”, “lower”, “below”, “above”, “on top”, “on the top”, “on”, etc. is used to explain a relationship between components shown in the drawings. The terms are relative concepts and are explained based on the direction indicated in the drawings.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments will be described in detail with reference to the accompanying drawings. The same reference numerals are used for the same components in the drawings, and redundant descriptions of the same components will be omitted.

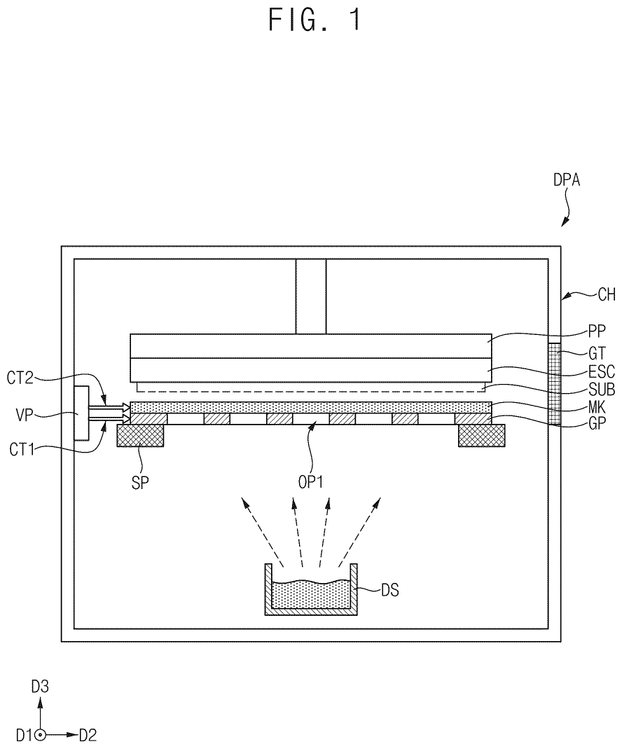

FIG. 1 is a cross-sectional view showing a deposition facility according to an embodiment of the present disclosure.

Referring to FIG. 1, a deposition apparatus DPA may include a chamber CH, a moving plate PP, an electrostatic chuck ESC, a deposition source DS, a voltage generator VP, a support member SP, a grid member GP, and a mask MK.

The chamber CB may protect the substrate SUB by providing an environment sealed from an outside, and may provide a space in which the substrate SUB is deposited. For example, the chamber CB may have a vacuum pressure (about 10 Torr to about 200 Torr) that is lower than the normal pressure (about 1 atmosphere or about 760 Torr). However, embodiments of the present disclosure are necessarily not limited thereto.

The chamber CB may include at least one gate GT. The chamber CH may be opened and closed by the gate GT. The substrate SUB may enter and exit through the gate GT provided in the chamber CH.

The moving plate PP may be disposed on an upper part of the chamber CH. The moving plate PP may be movable up and down or left and right. For example, the moving plate PP may position the substrate SUB on the mask MK.

An electrostatic conductor such as the electrostatic chuck ESC may be disposed on the moving plate PP. As voltage is applied to an electrode of the electrostatic chuck ESC, electrostatic force may be induced. For example, the electrostatic chuck ESC may support the substrate SUB by the electrostatic force. That is, the electrostatic chuck ESC may support the substrate SUB while a deposition process proceeds within the deposition apparatus DPA.

The deposition source DS may include a deposition material. The deposition material is a material capable of sublimation or vaporization and may include one or more of inorganic materials or organic materials. The deposition material evaporated from the deposition source DS may pass through the grid member GP and the mask MK and be deposited on the substrate SUB.

The voltage generator VP may apply voltage to inside of the deposition apparatus DPA. The voltage generator VP may include a first contact portion CT1 and a second contact portion CT2 extending from the voltage generator VP. The first contact portion CT1 and the second contact portion CT2 may apply a voltage applied from the voltage generator VP to an object. For example, the first contact portion CT1 may apply a first voltage, and the second contact portion CT2 may apply a second voltage.

In an embodiment, the first contact portion CT1 and the second contact portion CT2 may apply voltages of different polarities. For example, the first voltage applied by the first contact portion CT1 may be a positive voltage, and the second voltage applied by the second contact portion CT2 may be a negative voltage. For another example, the first voltage applied by the first contact portion CT1 may be a negative voltage, and the second voltage applied by the second contact portion CT2 may be a positive voltage.

The support member SP may be disposed on the deposition source DS. The support member SP may support the grid member GP and the mask MK. The support member SP may be disposed outside a movement path of the deposition material supplied from the deposition source DS to the substrate SUB.

The grid member GP may be disposed on the support member SP. The grid member GP may support the mask MK so that the mask MK does not sag in a direction (e.g., gravity direction) opposite to the third direction D3. That is, as the grid member GP supports the mask MK, distortion, unevenness, etc. of the mask MK may be effectively prevented or reduced. Accordingly, the deposition material evaporated from the deposition source DS may be accurately deposited on the substrate SUB without distortion.

In an embodiment, the grid member GP may have conductivity. The grid member GP may include metal, semiconductor materials, etc. For example, the grid member GP may include iron (Fe), platinum (Pt), gold (Au), silver (Ag), indium (In), gallium (Ga), tin (Sn), zirconium (Zr), vanadium (V), hafnium (Hf), cadmium (Cd), germanium (Ge), chromium (Cr), titanium (Ti), zinc (Zn), silicon (Si), etc. These may be used alone or in combination with each other. However, embodiments of the present disclosure are necessarily not limited thereto.

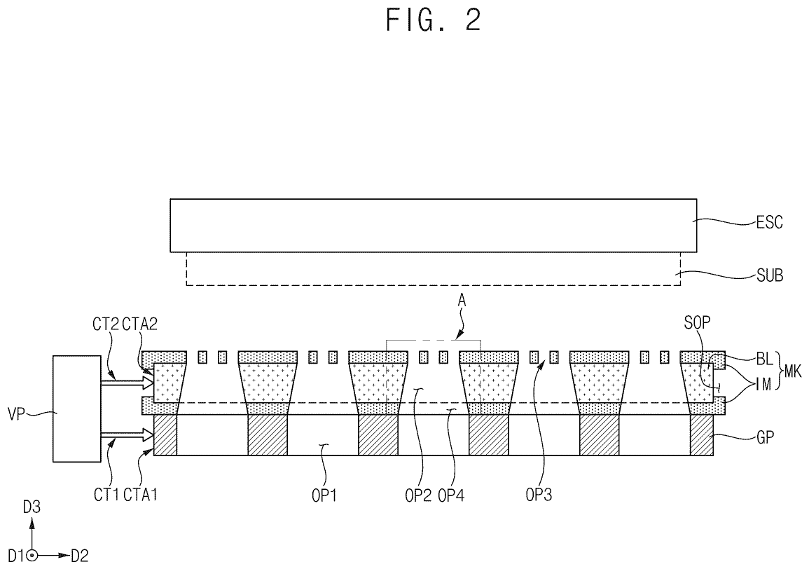

In an embodiment, the grid member GP may be electrically connected to the first contact portion CT1 of the voltage generator VP. Specifically, a first contact area (e.g., the first contact area CTA1 in FIG. 2) of the grid member GP may be electrically connected to the first contact portion CT1. That is, the first contact portion CT1 may contact the first contact area (e.g., the first contact area CTA1 in FIG. 2) of the grid member GP. Accordingly, the grid member GP may have a voltage that is substantially the same as the first voltage of the first contact portion CT1.

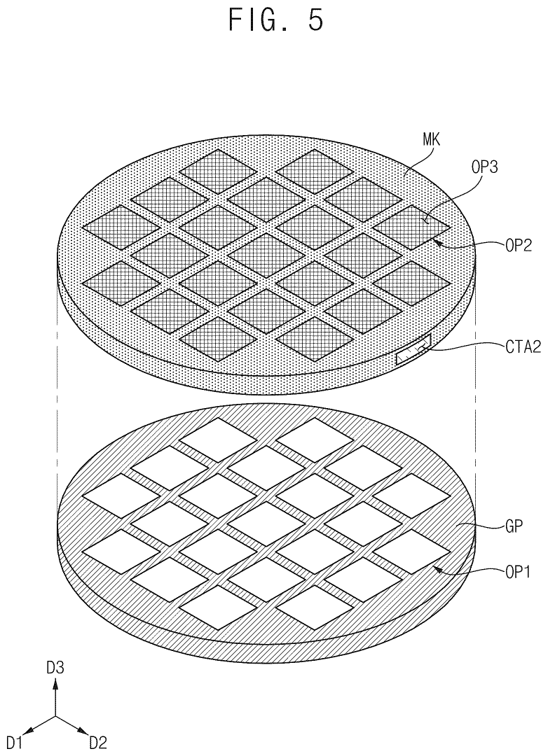

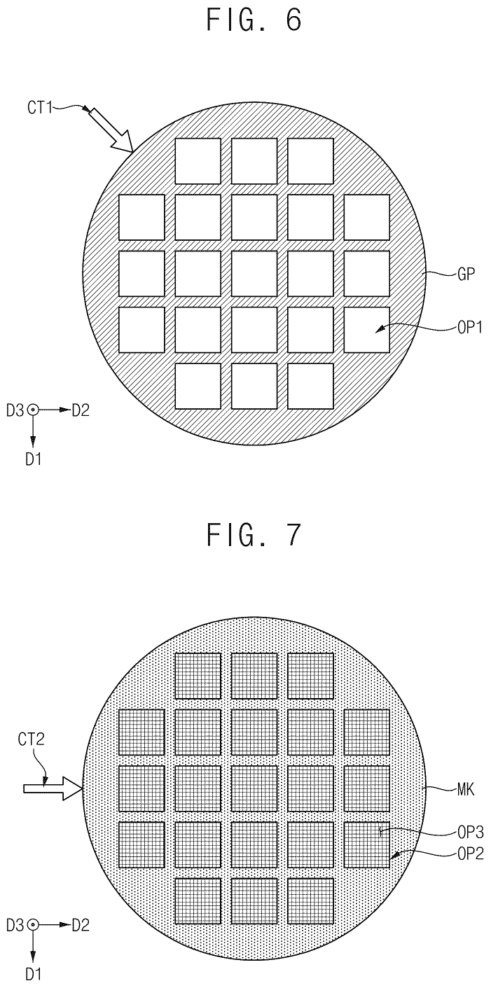

In an embodiment, the grid member GP may define first openings OP1 therein. The first openings OP1 may be areas through which a deposition material evaporated from the deposition source DS passes. The first openings OP1 of the grid member GP will be described later with reference to FIGS. 5 and 6.

The mask MK may be disposed on the grid member GP. The mask MK may define a plurality of openings therein so that the deposition material evaporated from the deposition source DS may be deposited at a preset position on the substrate SUB. The openings defined in the mask MK will be described later with reference to FIG. 2.

The mask MK may be electrically connected to the second contact portion CT2 of the voltage generator VP. Accordingly, the mask MK may have a voltage that is substantially the same as the second voltage of the second contact portion CT2.

As the grid member GP have the first voltage by connecting to the first contact portion CT1 and the mask MK have the second voltage opposite to the first voltage by connecting to the second contact portion CT2, an electrostatic force between the grid member GP and the mask MK may be formed.

That is, as a monopolar electrostatic force is generated between the mask MK (specifically, the base substrate BL) and the grid member GP in which an electrostatic force acts in one direction (e.g., third direction D3), the mask MK and the grid member GP may be strongly adsorbed in the third direction D3. Accordingly, as the grid member GP and the mask MK are adsorbed to each other, and the mask MK may not sag during a deposition process. As a result, in a deposition process using the deposition apparatus DPA, a reliability of deposition may be effectively improved because the mask MK does not sag in the gravity direction.

FIG. 2 is a cross-sectional view showing an embodiment of a deposition apparatus disposed inside the chamber of FIG. 1.

Referring to FIGS. 1 and 2, the mask MK may include a base substrate BL and an insulating layer IM. The insulating film IM may be disposed to surround a side surface, a top surface, and a bottom surface of the base substrate BL.

The insulating film IM may prevent the base substrate BL and the grid member GP from directly contacting each other. That is, the insulating film IM may prevent the base substrate BL and the grid member GP from directly contacting each other, thereby blocking current flow between the base substrate BL and the grid member GP. Accordingly, a voltage difference may occur between the base substrate BL and the grid member GP, allowing electrostatic force to be formed.

The insulating film IM may include a silicon oxide film, a silicon nitride film, a metal oxide film, etc. For example, the insulating film IM may include silicon oxide (SiOx), silicon nitride (SiNx), silicon oxynitride (SiOxNy), a metal oxide film, a metal nitride film, etc. These may be used alone or in combination with each other. However, embodiments of the present disclosure are necessarily not limited thereto.

The base substrate BL may have a conductivity. The base substrate BL may include metal, semiconductor materials, etc. For example, the base substrate BL may include iron (Fe), platinum (Pt), gold (Au), silver (Ag), indium (In), gallium (Ga), tin (Sn), zirconium (Zr), vanadium (V), hafnium (Hf), cadmium (Cd), germanium (Ge), chromium (Cr), titanium (Ti), zinc (Zn), silicon (Si), etc. These may be used alone or in combination with each other. However, embodiments of the present disclosure are necessarily not limited thereto.

In an embodiment, the base substrate BL may define second openings OP2 therein. The insulating film IM may define third openings OP3 therein and fourth openings OP4 therein. The second openings OP2, the third openings OP3, and the fourth openings OP4 are openings defined so that the deposition material may be deposited at a preset position of the substrate SUB.

For example, the third openings OP3 may be defined in the insulating film IM on a top surface of the base substrate BL, and the fourth openings OP4 may be defined in the insulating film IM on a bottom surface of the base substrate BL. That is, in a cross-sectional view, the third openings OP3 may be defined on the second openings OP2, and the fourth openings OP4 may be defined under the second openings OP2.

In an embodiment, two or more third openings OP3 may correspond to each of the second openings OP2. That is, the deposition material that has passed through the second openings OP2 may pass through a plurality of third openings OP3. That is, the third openings OP3 may form an arbitrary pattern. Accordingly, the deposition material may be deposited on the substrate SUB according to an arbitrary pattern formed by the third openings OP3.

In an embodiment, the second openings OP2 may overlap the fourth openings OP4 in a plan view. The second openings OP2 may correspond one-to-one with the fourth openings OP4. Accordingly, the deposition material that has passed through the first openings OP1 may sequentially pass through the fourth openings OP4 and the second openings OP2 and may be deposited on the substrate SUB. As used herein, the “plan view” is a view in a thickness direction (i.e., third direction D3) of the grid member GP.

In an embodiment, each of the second openings OP2 may overlap each of the first openings OP1 of the grid member GP in a plan view. For example, the first openings OP1 may correspond one-to-one with the second openings OP2. Accordingly, the deposition material that has passed through the first openings OP1 may pass through the second openings OP2 and may be deposited at a preset position of the substrate SUB. The second openings OP2 will be described later with reference to FIGS. 5 and 7.

In an embodiment, the insulating film IM may define a side opening SOP therein exposing the second contact area CTA2 on a side of the base substrate BL. That is, at least a portion of a side surface of the mask MK may be removed to expose the second contact area CTA2 of the base substrate BL. For example, the side opening SOP may be provided in plurality. Accordingly, a plurality of second contact areas CTA2 may be provided on the base substrate BL.

In an embodiment, the mask MK may be electrically connected to the second contact portion CT2 of the voltage generator VP. Specifically, the second contact area CTA2 of the base substrate BL included in the mask MK may contact the second contact portion CT2. Accordingly, the mask MK may have a voltage that is substantially the same as the second voltage of the second contact portion CT2.

As the second contact portion CT2, the second contact area CTA2, and the side opening SOP are provided in plurality, the base substrate BL may be applied the second voltage through at least two second contact areas CTA2. That is, even if one of the second contact portions CT2 does not contact the base substrate BL, the base substrate BL may reliably receive the second voltage from the second contact portion CT2 because another second contact portions CT2 contact the base substrate BL.

In addition, a plurality of first contact areas CTA1 and a plurality of first contact portions CT1 of the grid member GP may be provided. As the plurality of the first contact portions CT1 and the plurality of first contact areas CTA1 are provided, the grid member GP may be applied the first voltage through at least two first contact areas CTA1. That is, even if one of the first contact portions CT1 does not contact the grid member GP, the other one of the first contact portions CT1 may contact the grid member GP so that the member GP may reliably receive the first voltage from the first contact portion CT1.

In addition, a plurality of the first contact portion CT1 and a plurality of the second contact portion CT2 are provided and connected to the grid member GP and the base substrate BL, respectively, so that the deposition apparatus DPA reliability may be effectively improved.

In an embodiment, the mask MK and the grid member GP may physically contact each other. As the mask MK and the grid member GP are physically contacted, the mask MK and the grid member GP are attached to each other by electrostatic force, thereby effectively preventing sagging of the mask MK in the gravity direction.

In an embodiment, each of the second openings OP2 may have a trapezoidal shape in a cross-sectional view. However, embodiments of the present disclosure are necessarily not limited thereto. Each of the second openings OP2 may have a shape such as a rectangle in a cross-sectional view in another embodiment.

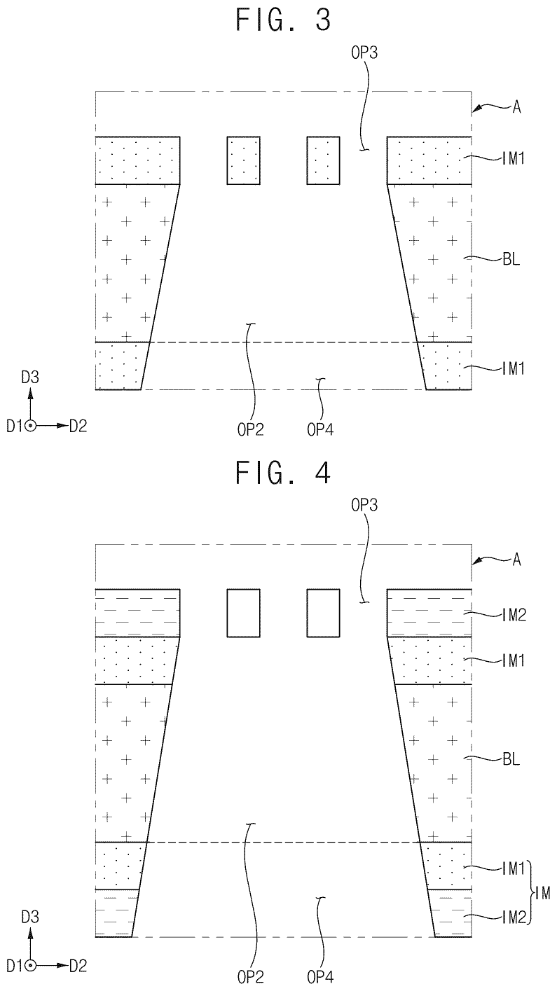

FIG. 3 is a cross-sectional view showing an enlarged embodiment of part A of FIG. 2. FIG. 4 is a cross-sectional view showing another embodiment of enlarged part A of FIG. 2.

Referring to FIGS. 2, 3, and 4, the insulating film IM may have a single-layer or multi-layer structure. For example, as shown in FIG. 3, the insulating film IM may have a single-layer structure (i.e., IM1). For another example, as shown in FIG. 4, the insulating layer IM may have a multilayer structure including a first insulating layer IM1 and a second insulating layer IM2. The first insulating layer IM1 and the second insulating layer IM2 may include different materials from each other. Since the insulating film IM surrounds a side surface, a top surface, and a bottom surface of the base substrate BL, the “single-layer” structure and the “multilayer” structure here mean a single shell structure and a multi-shell structure, respectively, such that when the insulating film has the single-layer structure, the single-layered insulating film IM1 covers the side surface, the top surface, and the bottom surface of the base substrate BL with openings therein as shown in FIG. 3.

FIG. 5 is a perspective view showing the mask and grid member of FIG. 2. FIG. 6 is a plan view showing an embodiment of the grid member of FIG. 5. FIG. 7 is a plan view showing an embodiment of the mask of FIG. 5.

Referring to FIGS. 2 and 5, the grid member GP may define a plurality of first openings OP1 therein, and the mask MK may define a plurality of second openings OP2 therein. The first openings OP1 may correspond one-to-one with the second openings OP2 and may overlap the second openings OP2 in a plan view.

In an embodiment, each of the first openings OP1 and the second openings OP2 may be defined in a mattress shape in the first direction D1 and/or the second direction D2. In addition, each of the first openings OP1 and the second openings OP2 may have a rectangular shape in a plan view. However, embodiments of the present disclosure are necessarily not limited thereto. Planar shapes (i.e., shapes in a plan view) of the first openings OP1 and the second openings OP2 may include various shapes such as circular, oval, and polygonal shapes in another embodiment.

In an embodiment, two or more third openings OP3 may correspond to each of the second openings OP2. As shown in FIG. 5, the third openings OP3 may form an arbitrary pattern in each of the second openings OP2. Accordingly, the deposition apparatus (e.g., the deposition apparatus DPA of FIG. 1) including the mask MK may deposit the deposition material in a desired area.

The second contact area CTA2 may be defined on a side of the mask MK. A plurality of second contact areas CTA2 may be defined on the mask MK. The second contact area CTA2 may contact the second contact portion CT2.

Referring further to FIGS. 6 and 7, the grid member GP may contact the first contact portion CT1, and the mask MK may contact the second contact portion CT2. In FIGS. 6 and 7, one first contact portion CT1 and one second contact portion CT2 are shown, but embodiments of the present disclosure are necessarily not limited thereto. Each of the first contact portion CT1 and the second contact portion CT2 may be provided in plural numbers in another embodiment.

In an embodiment, the first contact portion CT1 and the second contact portion CT2 may be spaced apart from each other in a plan view. That is, the first contact portion CT1 and the second contact portion CT2 may not overlap each other in a plan view. For example, as shown in FIGS. 6 and 7, the first contact portion CT1 may be disposed on one side of the grid member GP, and the second contact portion CT2 may be disposed at a position rotated about 45 degrees from the first contact portion CT1 in a plan view. In FIGS. 6 and 7, the first contact part CT1 and the second contact part CT2 are disposed by rotating about 45 degrees, but the embodiment of the present disclosure is not limited thereto. The first contact portion CT1 and the second contact portion CT2 may be disposed to rotate each other by about 1 degree or more and about 180 degrees or less in a plan view in another embodiment.

As the first contact portion CT1 and the second contact portion CT2 are disposed to be spaced apart from each other in a plan view, the first contact portion CT1 and the second contact portion CT2 may not contact each other. Accordingly, a short phenomenon between the first contact portion CT1 and the second contact portion CT2 may be effectively prevented or reduced. As a result, a preset voltage is applied to the grid member GP and the mask MK, so that the grid member GP and the mask MK may be attached by electrostatic force.

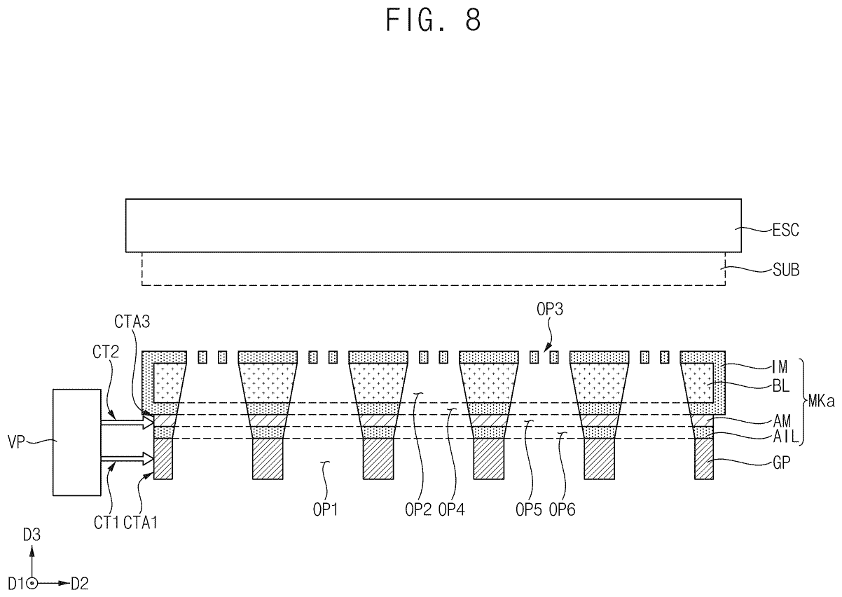

FIG. 8 is a cross-sectional view showing another embodiment of the deposition apparatus disposed inside the chamber of FIG. 1.

Referring to FIGS. 1, 2, and 8, the mask MKa may include the base substrate BL, the insulating film IM, a lower electrode layer AM, and a lower insulating layer AIL. That is, the lower electrode layer AM and the lower insulating layer AIL may be additionally disposed under the mask MK of FIG. 2 to form the mask MKa of FIG. 8.

The insulating layer IM of the mask MKa may not define the side opening SOP therein. That is, the insulating film IM of the mask MKa may define the third openings OP3 therein and the fourth openings OP4 therein, and may not define the side opening SOP therein on a side of the mask MKa. Since the insulating film IM of the mask MKa does not define the side opening SOP therein, the base substrate BL of the mask MKa may not contact the second contact portion CT2. However, because the lower electrode layer AM of the mask MKa contacts the second contact portion CT2, the mask MKa may receive the second voltage from the second contact portion CT2.

The lower electrode layer AM may be disposed under the insulating film IM. The lower electrode layer AM may be disposed under the insulating film IM as physically contacts with the insulating film IM. As the lower electrode layer AM physically contacts the insulating film IM, when the lower electrode layer AM and the grid member GP are adsorbed by electrostatic force, the base substrate BL and the insulating film IM may be stably adsorbed.

The lower electrode layer AM may have conductivity. However, the lower electrode layer AM may be electrically insulated from the base substrate BL by the insulating film IM. The lower electrode layer AM may include a metal material. For example, the lower electrode layer AM may include iron (Fe), platinum (Pt), gold (Au), silver (Ag), indium (In), gallium (Ga), tin (Sn), zirconium (Zr), vanadium (V), hafnium (Hf), cadmium (Cd), germanium (Ge), chromium (Cr), titanium (Ti), zinc (Zn), silicon (Si), etc. These may be used alone or in combination with each other. However, embodiments of the present disclosure are necessarily not limited thereto.

In an embodiment, the lower electrode layer AM may define fifth openings OP5 therein. For example, the fifth openings OP5 may correspond one-to-one with the fourth openings OP4. That is, the deposition material passing through the fifth openings OP5 in the third direction D3 may pass through the fourth openings OP4.

In an embodiment, the second contact portion CT2 may contact the lower electrode layer AM. For example, the second contact portion CT2 may contact a third contact area CTA3 defined on a side of the lower electrode layer AM. That is, the voltage generator VP may apply a voltage to the mask MKa through the third contact area CTA3 of the lower electrode layer AM. The third contact area CTA3 may be provided in plural numbers.

The lower insulating layer AIL may be disposed under the lower electrode layer AM. The lower insulating layer AIL may include substantially the same material as the insulating film IM. The lower insulating layer AIL may physically contact with the grid member GP and the lower electrode layer AM. As the lower insulating layer AIL physically contact with the grid member GP and the lower electrode layer AM, when the lower electrode layer AM and the grid member GP are adsorbed by electrostatic force (especially, monopolar electrostatic force), the lower electrode layer AM and the grid member GP may be stably adsorbed. The base substrate BL, the insulating film IM, the lower electrode layer AM, and the lower insulating layer AIL of the mask MKa may be physically connected without being separated.

In an embodiment, the lower insulating layer AIL may define sixth openings OP6 therein. For example, the sixth openings OP6 may correspond one-to-one with the fifth openings OP5. That is, a deposition material passing through the sixth openings OP6 in the third direction D3 may pass through the fifth openings OP5.

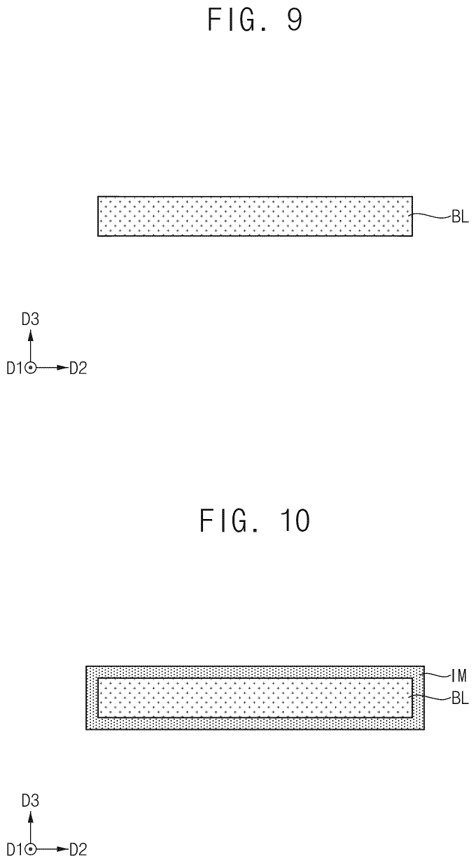

FIGS. 9, 10, 11, 12, 13, 14, and 15 are views showing a method of manufacturing the deposition apparatus of FIG. 2.

Referring to FIGS. 9 and 10, the base substrate BL having conductivity may be provided, and the insulating film IM may be formed to surround a side surface, a top surface and a bottom surface of the base substrate BL. The insulating film IM may be formed through a deposition process or the like. The insulating film IM may include silicon oxide, silicon nitride, metal oxide, etc.

Referring further to FIGS. 1 and 11, the third openings OP3 may be formed in the insulating film IM. The third openings OP3 may be formed through an exposure process or the like. The third openings OP3 may be openings that form an arbitrary pattern of the mask (e.g., the mask MK in FIG. 2). That is, the third openings OP3 may be openings formed in an arbitrary pattern to enable deposition at a preset position of the substrate SUB.

The third openings OP3 may be formed on the base substrate BL in a cross-sectional view. The third openings OP3 are formed on the base substrate BL and may be used as passages used when forming patterns. That is, the deposition material may pass through the third openings OP3 in the third direction D3 and be deposited on the substrate SUB.

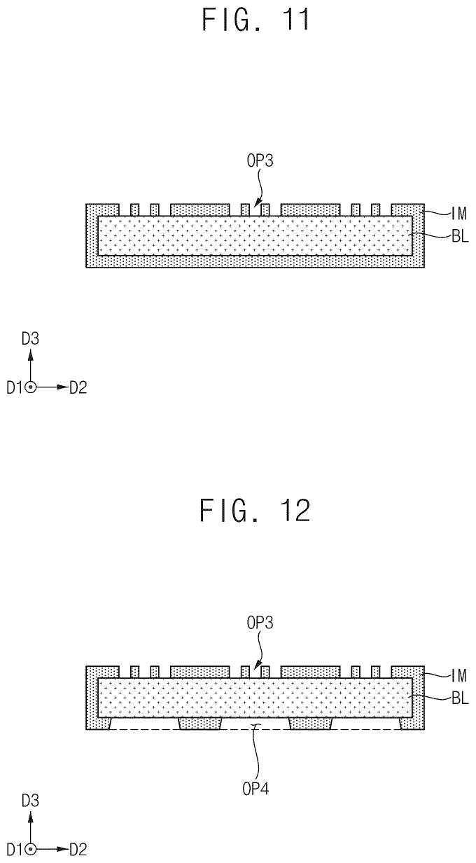

Referring further to FIG. 12, the fourth openings OP4 may be formed in the insulating film IM. The fourth openings OP4 may be formed under the base substrate BL in a cross-sectional view. The fourth openings OP4 may also be formed through substantially the same method as the third openings OP3.

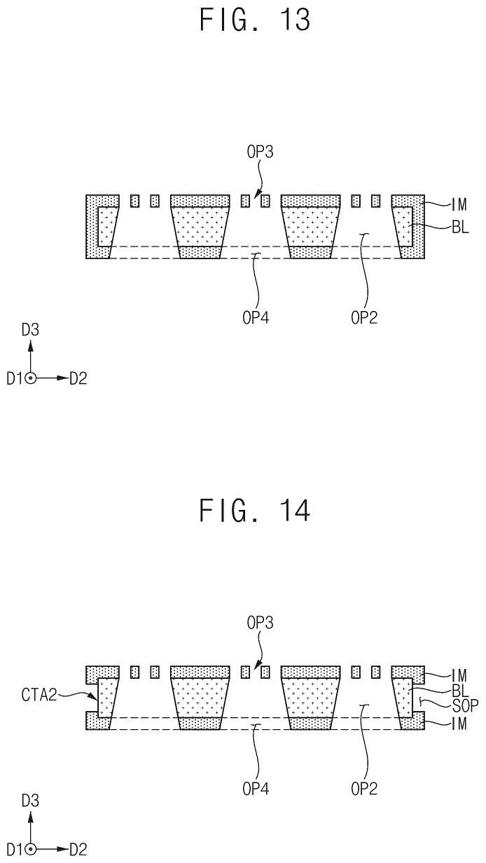

Referring further to FIG. 13, the second openings OP2 may be formed in the base substrate BL. The second openings OP2 may be formed to correspond one-to-one with the fourth openings OP4. That is, materials passing through the fourth openings OP4 in the third direction D3 may pass through the second openings OP2. In addition, two or more third openings OP3 may correspond to each of the second openings OP2.

Referring further to FIG. 14, the side opening SOP exposing the second contact area CTA2 of the base substrate BL may be formed in a side surface of the insulating film IM. In FIG. 14, two side openings SOPs are shown, but the embodiment of the present disclosure is not limited thereto. One or three or more side openings SOPs may be formed in the insulating film IM in another embodiment.

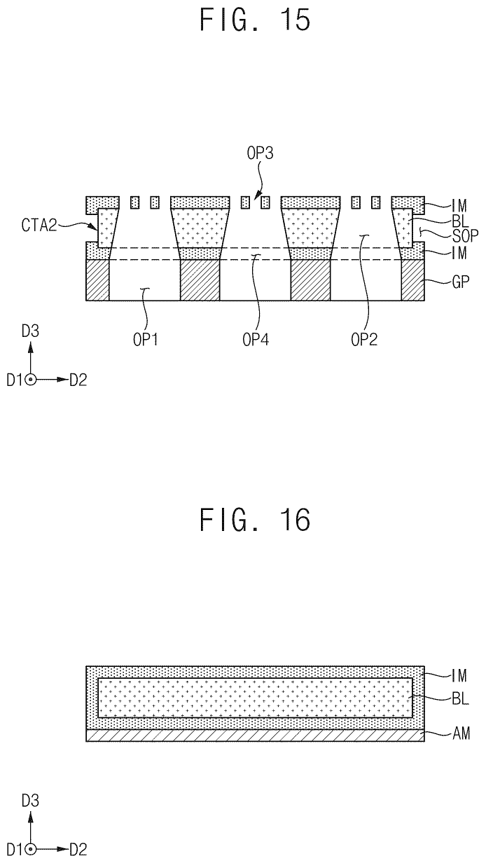

Referring further to FIG. 15, the grid member GP that defines the first openings OP1 therein and has conductivity may be disposed under the insulating film IM. The first openings OP1 may correspond one-to-one with the second openings OP2 and the fourth openings OP4. The grid member GP may be insulated from the base substrate BL by the insulating film IM.

FIGS. 16, 17, 18, 19, 20 and 21 are views showing a method of manufacturing the deposition apparatus of FIG. 8. Specifically, FIGS. 16, 17, 18, 19, 20 and 21 show a manufacturing method of further forming the lower electrode layer AM and the lower insulating layer AIL on the base substrate BL and the insulating film IM formed by steps shown in FIGS. 9 and 10.

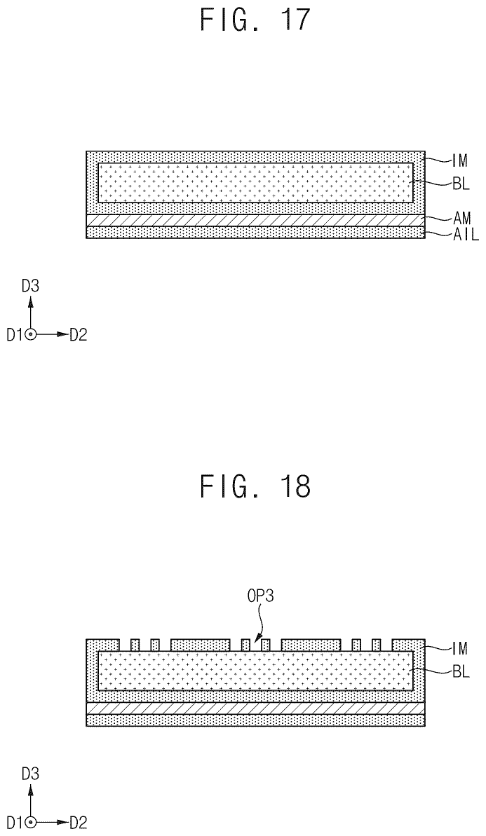

Referring to FIGS. 16 and 17, the lower electrode layer AM and the lower insulating layer AIL may be sequentially formed under the insulating film IM. That is, the lower electrode layer AM may be formed under the insulating film IM, and the lower insulating layer AIL may be formed under the lower electrode layer AM.

For example, the lower electrode layer AM may include metal, semiconductor, etc. The lower insulating layer AIL may include substantially the same material as the insulating film IM. However, embodiments of the present disclosure are necessarily not limited thereto.

Referring further to FIG. 18, the third openings OP3 may be formed in the insulating film IM. The third openings OP3 may be formed through an exposure process or the like. Since the third openings OP3 are substantially the same as those described with reference to FIG. 11, redundant information may be omitted or simplified.

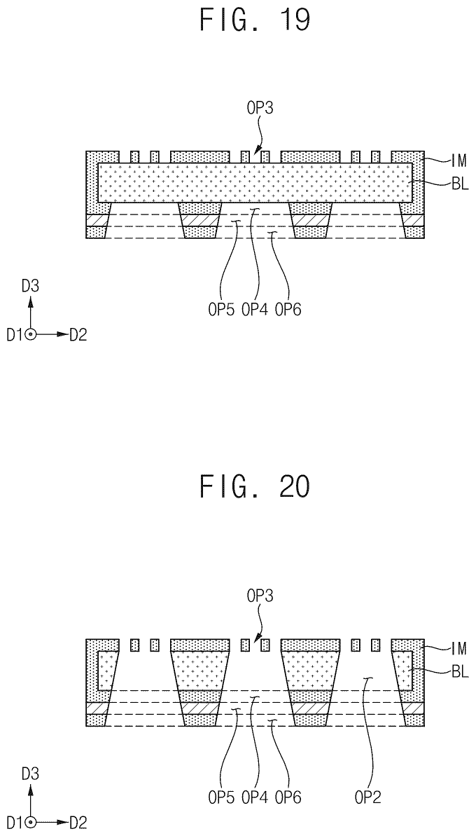

Referring further to FIG. 19, the fourth openings OP4, fifth openings OP5, and sixth openings OP6 may be formed in the insulating film IM, the lower electrode layer AM, and the lower insulating layer AIL, respectively. That is, the fourth openings OP4 may be formed in the insulating film IM, the fifth openings OP5 may be formed in the lower electrode layer AM, and the sixth openings OP5 may be formed in the lower insulating layer AIL.

The fourth openings OP4, the fifth openings OP5, and the sixth openings OP6 may be formed simultaneously or sequentially. In an embodiment, the fourth openings OP4, the fifth openings OP5, and the sixth openings OP6 may be formed to correspond each other in a one-to-one manner.

Referring further to FIG. 20, the second openings OP2 may be formed in the base substrate BL. The second openings OP2 may be formed to correspond one-to-one with the fourth openings OP4. That is, the second openings OP2 may overlap the fourth openings OP4 in a plan view. The second openings OP2 may be formed using substantially the same manufacturing method as described with reference to FIG. 13. Therefore, overlapping content may be omitted or simplified.

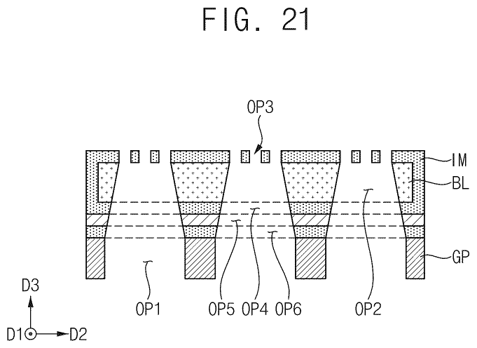

Referring further to FIG. 21, the grid member GP that defines the first openings OP1 therein and has conductivity may be disposed under the lower insulating layer AIL. The first openings OP1 may correspond one-to-one with the second openings OP2. The grid member GP may be insulated from the base substrate BL and the lower electrode layer AM by the lower insulating layer AIL.

The present disclosure may be applied to the display device and the electronic device including a same. For example, the present disclosure may be applied to high-resolution smartphones, mobile phones, smart pads, smart watches, tablet PCs, vehicle navigation systems, televisions, computer monitors, laptops, etc.

While the disclosure has been particularly shown and described with reference to embodiments thereof, it will be understood by those of ordinary skill in the art that various changes in form and details may be made therein without departing from the spirit or scope of the disclosure as defined by the following claims.

What is claimed is:

1. A deposition apparatus comprising:
a voltage generator including a first contact portion configured to apply a first voltage and a second contact portion configured to apply a second voltage having an opposite polarity to the first voltage;
a grid member having conductivity, electrically connected to the first contact portion, and defining first openings therein; and
a mask disposed on the grid member, electrically connected to the second contact portion, and including:
a base substrate defining second openings therein; and
an insulating film surrounding the base substrate and defining third openings therein on a top surface of the base substrate and fourth openings therein on a bottom surface of the base substrate.

2. The deposition apparatus of claim 1, wherein the first openings correspond one-to-one with the second openings.

3. The deposition apparatus of claim 1, wherein two or more third openings among the third openings correspond to each of the second openings.

4. The deposition apparatus of claim 1, wherein the fourth openings correspond one-to-one with the second openings.

5. The deposition apparatus of claim 1, wherein the first contact portion contacts a first contact area on a side of the grid member.

6. The deposition apparatus of claim 5, wherein the base substrate has conductivity and is electrically connected to the second contact portion,
the second contact portion contacts a second contact area on a side of the base substrate, and
the insulating film defines a side opening therein exposing the second contact area on the side of the base substrate.

7. The deposition apparatus of claim 6, wherein each of the second contact portion, the second contact area, and the side opening is provided in plural numbers.

8. The deposition apparatus of claim 1, wherein the insulating film is a single layer or a multilayer.

9. The deposition apparatus of claim 1, wherein the mask and the grid member physically contact with each other.

10. The deposition apparatus of claim 1, wherein the first contact portion and the second contact portion are spaced apart from each other in a plan view.

11. The deposition apparatus of claim 1, wherein each of the second openings has a trapezoidal shape in a cross-sectional view.

12. The deposition apparatus of claim 1, wherein the mask further includes:
a lower electrode layer disposed under the insulating film, having conductivity, and electrically connected to the second contact portion; and
a lower insulating layer disposed under the lower electrode layer.

13. The deposition apparatus of claim 12, wherein the lower electrode layer defines fifth openings therein, which correspond one-to-one with the fourth openings, and
the lower insulating layer defines sixth openings therein, which correspond one-to-one with the fifth openings.

14. The deposition apparatus of claim 12, wherein the second contact portion contacts a third contact area on a side of the lower electrode layer.

15. The deposition apparatus of claim 12, wherein the lower electrode layer is electrically insulated from the base substrate.

16. The deposition apparatus of claim 12, wherein the lower insulating layer and the grid member physically contact with each other.

17. The deposition apparatus of claim 12, wherein the lower insulating layer includes a same material as the insulating film.

18. A method of manufacturing a deposition apparatus, comprising:
providing a base substrate having conductivity;
forming an insulating film surrounding the base substrate;
forming first openings in the insulating film on a top surface of the base substrate and second openings in the insulating film on a bottom surface of the base substrate;
forming third openings in the base substrate corresponding one-to-one with the second openings;
forming a side opening in the insulating film exposing a contact area on a side of the base substrate; and
disposing a grid member under the insulating film, which has conductivity and defines fourth openings therein, which correspond one-to-one with the third openings.

19. The method of claim 18, wherein the side opening is provided in a plurality.

20. The method of claim 18, wherein two or more first openings among the first openings correspond to each of the third openings.
